(19) United States
(12) Patent Application Publication
(10) Pub. No.: US 2016/0064459 A1
(43) Pub. Date: Mar. 3, 2016

(54) ORGANIC LIGHT-EMITTING DIODE CONTACT IMPEDANCE TESTING DEVICE

(71) Applicant: EverDisplay Optronics (Shanghai) Limited, Shanghai (CN)

(72) Inventor: Chia-Che Hsu, Shanghai (CN)

(73) Assignee: EverDisplay Optronics (Shanghai) Limited

(21) Appl. No.: 14/482,727

(22) Filed: Sep. 10, 2014

(30) Foreign Application Priority Data
Aug. 28, 2014 (CN) 201410431193.6

(51) Int. Cl. H01L 27/32; H01L 51/52

(52) U.S. Cl. CPC H01L 27/3223; H01L 51/5206; H01L 51/5228; H01L 27/3272

(57) ABSTRACT

An organic light-emitting diode (OLED) contact impedance testing device includes an organic light-emitting diode cathode material layer located in an organic light-emitting diode panel. A plurality of test points is located on an edge of the organic light-emitting diode panel. A plurality of connecting lines connects the organic light-emitting diode cathode material layer to the test points. Each test point is partially superimposed by one of the connecting lines. Each connecting line is partially superimposed by the organic light-emitting diode cathode material layer. The OLED contact impedance testing device can rapidly detect the contact impedances of different components in the OLED panel. Thus, problems in the complicated OLED panel can rapidly be located through measurement of the impedances.

### CROSS-REFERENCE TO RELATED APPLICATION

The present invention claims the benefit of priority to CN 201410431193.6, filed on Aug. 28, 2014 with the State Intellectual Property Office of the People's Republic of China, the specification of which is herein incorporated in its entirety by reference.

### BACKGROUND OF THE INVENTION

The present invention relates to an organic light-emitting diode (OLED) panel testing device and, more particularly, to an organic light-emitting diode (OLED) contact impedance testing device.

Active matrix organic light-emitting diodes (AMOLED) are a display technology of the new generation and include advantages of self-illumination, broad view, contrast ratio, low power consumption, high speed response, high resolution, full color, and a thinned structure.

Currently, a low temperature poly silicon (LTPS) process is used to produce the back plate of an AMOLED, and an OLED evaporation and encapsulation process and a module polarizing film and IC bonding process are carried out to obtain a panel display.

FIG. 1 shows a conventional OLED panel. During light emission of the OLED panel, an OLED driving unit 44 of an AMOLED panel uses the switch characteristics of a thin-film transistor (TFT) to transmit a hole current signal from an anode 43 of the OLED driving unit 44 to an anode 42 of a corresponding OLED. At the same time, an electron current signal is transmitted by a cathode material layer 33 of the OLED to the corresponding OLED. The electron and hole combine with each other at the emission layer (EML) to generate a self-illumination effect.

As mentioned above, the AMOLED panel includes a complicated structure produced by many complicated steps. However, there is no effective monitoring mechanism for monitoring the problems resulting from deficient processes related to the anode and the cathode, such as high electrical impedance of the anode, high electrical impedance of the cathode, poor photo-detection (PD) taper profile, contamination of the cathode interface, and contamination of the anode interface, which result in low illuminating efficiency or even malfunction in illumination. Thus, if an AMOLED has poor illuminating efficiency, a long period of time is often required to find out the cause. Thus, it is difficult to prevent in a short time and, thus, causes an increase in the manufacturing costs.

### BRIEF SUMMARY OF THE INVENTION

An objective of the present invention is to provide an organic light-emitting diode (OLED) contact impedance testing device, wherein the contact impedances of some components in an OLED panel can be measured by the OLED contact impedance testing device to rapidly locate the problems that occur during the manufacturing processes of the AMOLED.

To solve the above problem and other problems, the present invention provides an organic light-emitting diode (OLED) contact impedance testing device including an organic light-emitting diode cathode material layer adapted to be located in an organic light-emitting diode panel. A plurality of test points is located on an edge of the organic light-emitting diode panel. A plurality of connecting lines connects the organic light-emitting diode cathode material layer to the plurality of test points. Each of the plurality of test points is partially superimposed by one of the plurality of connecting lines. Each of the plurality of connecting lines is partially superimposed by the organic light-emitting diode cathode material layer.

The areas of the plurality of test points respectively superimposed by the plurality of connecting lines can be equal to each other.

The areas of the plurality of connecting lines superimposed by the organic light-emitting diode cathode material layer can be equal to each other.

The plurality of connecting lines and an organic light-emitting diode anode in the organic light-emitting diode panel can be made of the same material.

The plurality of connecting lines can be made of a silver film and an indium tin oxide film.

The plurality of test points and an anode of an organic light-emitting diode driving unit in the organic light-emitting diode panel can be made of the same material.

The organic light-emitting diode cathode material layer can be made of a magnesium aluminum alloy.

The OLED contact impedance testing device can further include a cover glass mounted on top of the organic light-emitting diode cathode material layer.

The OLED contact impedance testing device according to the present invention can rapidly detect the contact impedances of different components in the OLED panel. Thus, problems in the complicated OLED panel can rapidly be located through measurement of the impedances.

The present invention will become clearer in light of the following detailed description of illustrative embodiments of this invention described in connection with the drawings.

### DESCRIPTION OF THE DRAWINGS

FIG. 1 is a cross sectional view of a conventional OLED panel.

FIG. 2 is a top view of an organic light-emitting diode (OLED) contact impedance testing device according to the present invention.

FIG. 3 is a cross sectional view of the OLED contact impedance testing device according to the present invention.

FIG. 4 is a top view of the OLED contact impedance testing device according to the present invention after production of test points.

FIG. 5 is a cross sectional view of the OLED contact impedance testing device of FIG. 4.

FIG. 6 is a top view of the OLED contact impedance testing device according to the present invention after production of connecting liens.

FIG. 7 is a cross sectional view of the OLED contact impedance testing device of FIG. 6.

FIG. 8 is a top view of the OLED contact impedance testing device according to the present invention after production of a cathode material layer.

FIG. 9 is a cross sectional view of the OLED contact impedance testing device of FIG. 8.

### DETAILED DESCRIPTION OF THE INVENTION

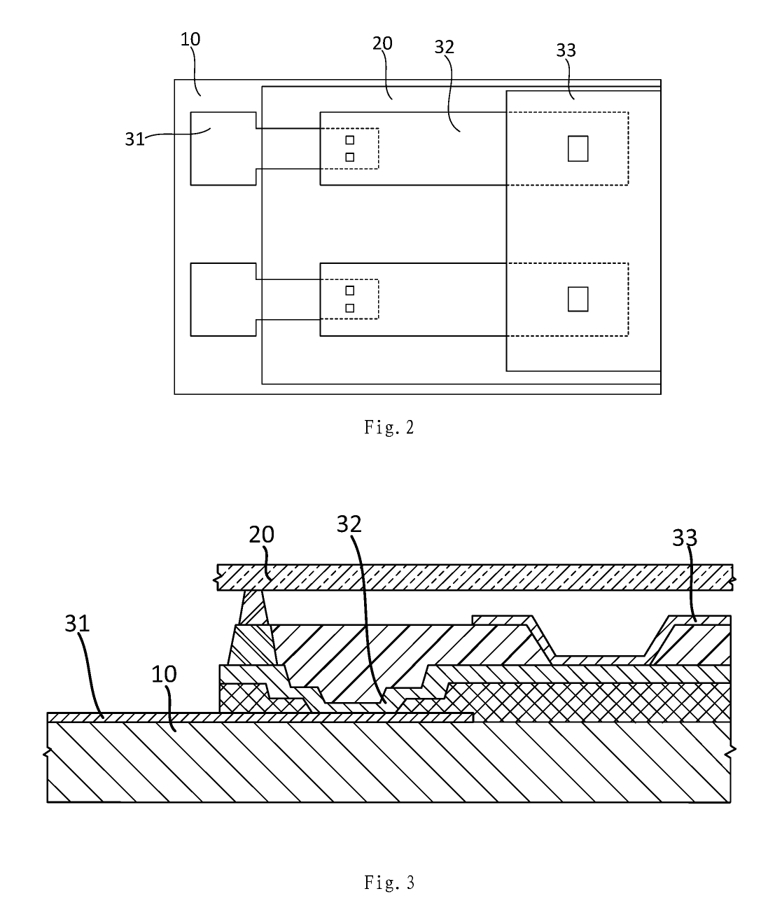

With reference to FIGS. 2 and 3, an organic light-emitting diode (OLED) contact impedance testing device according to the present invention includes an organic light-emitting diode (OLED) cathode material layer 33, a plurality of test points 31, and a plurality of connecting lines 32 connecting the OLED cathode material layer 33 to the test points 31.

The OLED cathode material layer 33 is located in an organic light-emitting diode (OLED) panel. The OLED cathode material layer 33 is the common cathode of all OLEDs of the OLED panel and is connected to all of the connecting lines 32. In this embodiment, the OLED cathode material layer 33 is made of a magnesium aluminum alloy. Since the magnesium aluminum alloy is an easy-to-oxide material, the OLED cathode material layer 33 must be packaged between a glass substrate 10 and a cover glass 20.

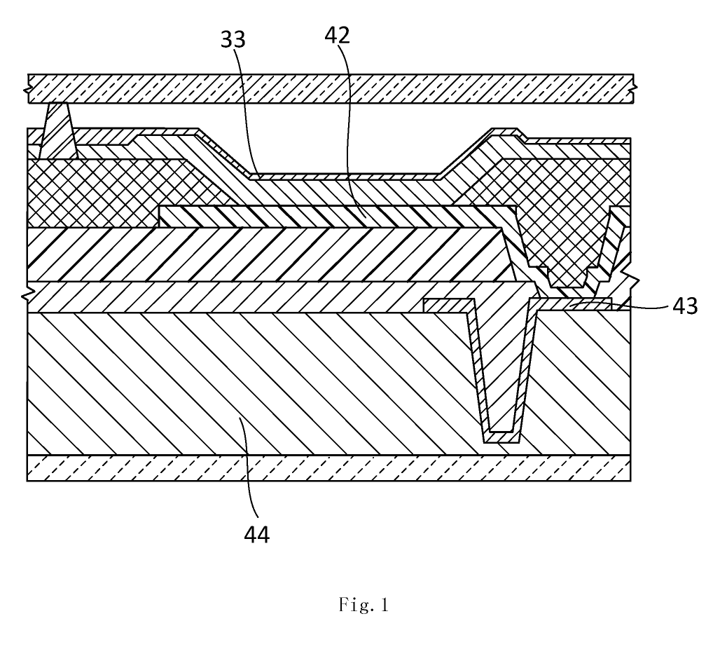

The test points 31 are located on an edge of the OLED panel and are located on top of the glass substrate 10. Nevertheless, the test points 31 are not covered by the cover glass 20 but are exposed outside of the OLED panel. The number of the test points 31 is more than one. The test points 31 and an anode 43 (c.f. FIG. 1) of an OLED driving unit are made of the same material. In this embodiment, the tests points 31 are made of aluminum. Since the test points 31 are exposed outside of the OLED panel, a probe can be used to directly contact the test points 31 for detection purposes.

An end of each connecting line 32 is connected to the OLED cathode material layer 33. The other end of each connecting line 32 is connected to one of the test points 31. The connecting lines 32 are packaged between the glass substrate 10 and the cover glass 20. In this embodiment, the connecting lines 32 and the OLED anode 42 (c.f. FIG. 1) are made of a silver (Ag) film and an indium tin oxide (ITO) film.

As can be seen from FIGS. 2 and 3, each test point 31 is partially superimposed by one of the connecting lines 32 to achieve connection therebetween. To assure consistency of the detected data, the areas of the test points 31 respectively superimposed by the connecting lines 32 are equal to each other. Likewise, each connecting line 32 is superimposed by the OLED cathode material layer 33 to achieve connection therebetween. To assure consistency of the detected data, the areas of the connecting lines 32 superimposed by the OLED cathode material layer 33 are equal to each other.

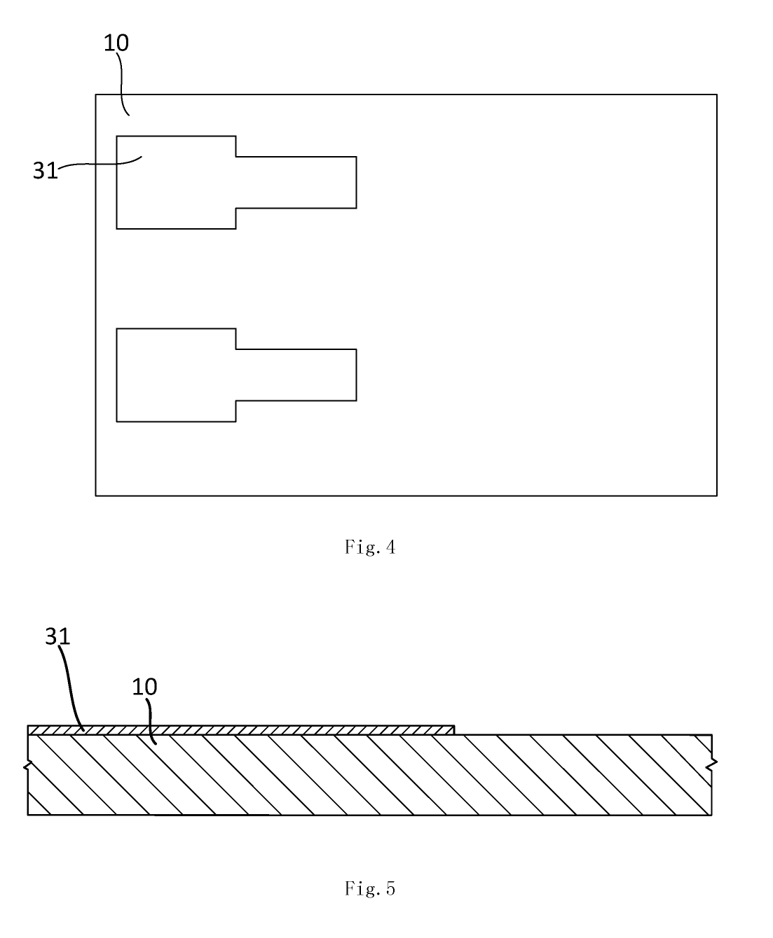

FIGS. 4-9 show manufacturing processes of the OLED contact impedance testing device according to the present invention. With reference to FIGS. 4 and 5, test points 31 are firstly produced on an edge of an upper side of a glass substrate 10. In this embodiment, the test points 31 are made of aluminum. Since aluminum has stable chemical properties in the air, it is not necessary to package the test points 31 between the glass substrate 10 and a cover glass 20 in subsequent processing. Nevertheless, a portion of each test point 31 is packaged between the glass substrate 10 and the cover glass 20.

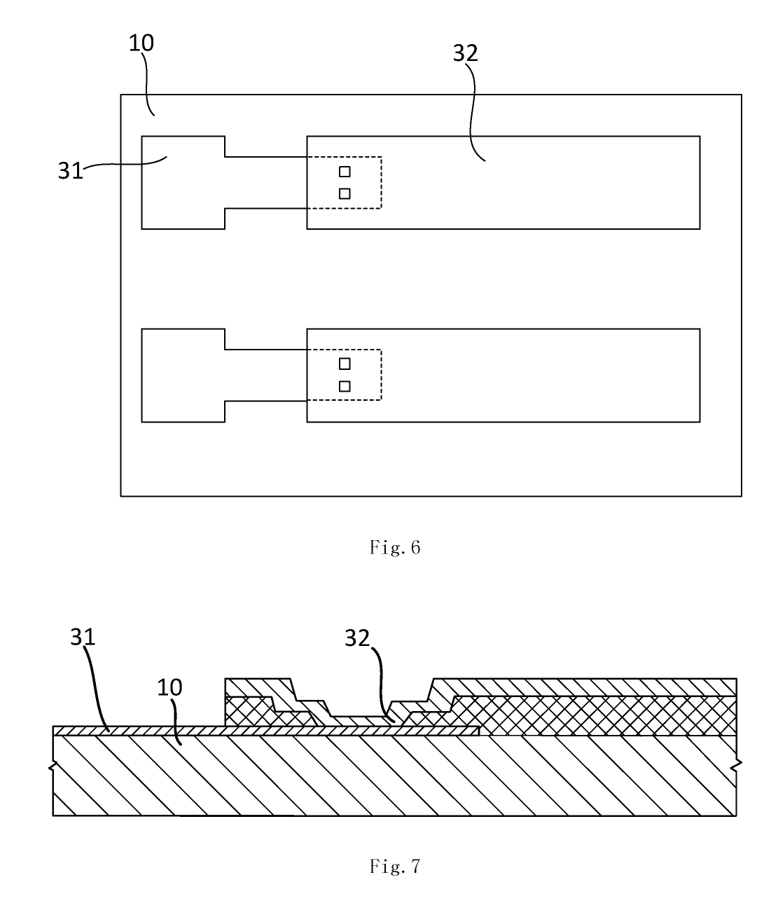

After production of the test points 31, connecting lines 32 connected to the test points 31 are produced on top of the test points 31, as shown in FIGS. 6 and 7. An end portion of each connecting line 32 superimposes on one of the test points 31 to connect the connecting lines 32 and the test points 31. In this embodiment, the connecting lines 32 and the OLED anode 42 are made of a silver (Ag) film and an indium tin oxide (ITO) film.

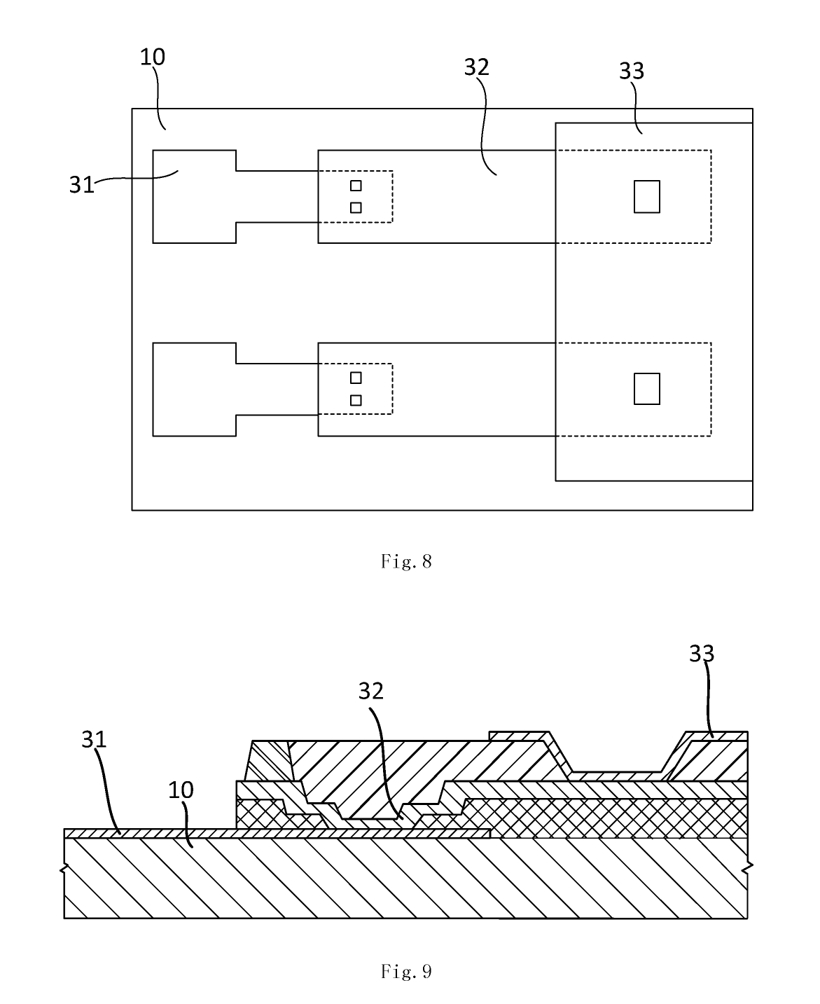

With reference to FIGS. 8 and 9, after production of the connecting lines 32, an OLED cathode material layer 33 is produced on top of the connecting lines 32. After production of the OLED cathode material layer 33, the glass cover 20 is used to package the OLED cathode material layer 33 and the connecting lines 33, obtaining the OLED contact impedance testing device shown in FIGS. 2 and 3 after packaging. The OLED cathode material layer 33 is the common cathode of all OLEDs in the OLED panel and is connected to all of the connecting lines 32. In this embodiment, the OLED cathode material layer 33 is made of a magnesium aluminum alloy. Since the magnesium aluminum alloy is an easy-to-oxide material, the OLED cathode material layer 33 must be packaged between the glass substrate 10 and the cover glass 20.

As can be seen from FIG. 2, when using the OLED contact impedance testing device to proceed with detection, two different test points 31 are selected, and a probe is used to test the impedance from one of the test points 31 to the other. The detected impedance value consists of the impedances of the conductors and contact points between the two test points 31, including the contact impedance R₁₂ of the test points 31 (whose material is the same as the anode 43 of the OLED driving unit) and the connecting lines 32 (whose material is the same as the OLED anode 42) and the contact impedance R₂₃ of the connecting lines 32 and the OLED cathode material layer 33. The OLED contact impedance testing device according to the present invention can rapidly detect the contact impedances of different components in the OLED panel, which is advantageous over the prior art in which the components in regular OLED panels cannot directly be measured as being packaged in the cover glass 20.

Conclusively, the OLED contact impedance testing device according to the present invention can rapidly detect the contact impedances of different components in the OLED panel. Thus, problems in the complicated OLED panel can rapidly be located through measurement of the impedances.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. An organic light-emitting diode contact impedance testing device for an organic light-emitting diode panel, comprising:
an organic light-emitting diode cathode material layer adapted to be located in the organic light-emitting diode panel;
a plurality of test points located on an edge of the organic light-emitting diode panel; and
a plurality of connecting lines connecting the organic light-emitting diode cathode material layer to the plurality of test points, with each of the plurality of test points partially superimposed by one of the plurality of connecting lines, and with each of the plurality of connecting lines partially superimposed by the organic light-emitting diode cathode material layer.

2. The device as claimed in claim 1, wherein areas of the plurality of test points respectively superimposed by the plurality of connecting lines are equal to each other.

3. The device as claimed in claim 1, wherein areas of the plurality of connecting lines superimposed by the organic light-emitting diode cathode material layer are equal to each other.

4. The device as claimed in claim 3, wherein an organic light-emitting diode anode is adapted to be formed inside the organic light-emitting diode panel and wherein the plurality of connecting lines and the organic light-emitting diode anode of the organic light-emitting diode panel are made of same material.

5. The device as claimed in claim 4, wherein the plurality of connecting lines is made of a silver film and an indium tin oxide film.

6. The device as claimed in claim 1, wherein an organic light-emitting diode driving unit having an anode is adapted to be formed inside the organic light-emitting diode panel, and wherein the plurality of test points and the anode of the organic light-emitting diode driving unit of the organic light-emitting diode panel are made of same material.

7. The device as claimed in claim 1, wherein the material for the organic light-emitting diode cathode layer is of magnesium aluminum alloy.

8. The device as claimed in claim 1 further comprising a cover glass mounted on top of the organic light-emitting diode cathode material layer.
